(19) United States
(12) Patent Application Publication
(10) Pub. No.: US 2006/0143993 A1
(43) Pub. Date: Jul. 6, 2006

(54) Slurry compositions for use in chemical mechanical polishing and method of manufacturing semiconductor device using the same

(76) Inventors: Sung-Jun Kim, Hwaseong-si (KR); Chang-Ki Hong, Seongnam-si (KR); Jae-Dong Lee, Suwon-si (KR); Jae-Kwang Choi, Suwon-si (KR)

Correspondence Address: HARNESS, DICKEY & PIERCE, P.L.C., P.O. BOX 8910, RESTON, VA, 20195, US

(21) Appl. No.: 11/325,483

(22) Filed: Jan. 5, 2006

(30) Foreign Application Priority Data
Jan. 5, 2005 (KR) 2005-00935

(51) Int. Cl. C09G 1/02; C09K 3/14; H01L 21/302

(52) U.S. Cl. 51/307; 438/691; 51/308; 51/309; 106/3

(57) ABSTRACT

Slurry compositions and method used in a chemical-mechanical polishing process for manufacturing a semiconductor device may include a surfactant and a positive-ionic high molecular compound. The surfactant and the positive-ionic high molecular compound may form first and second passivation layers on the surface of an exposed polysilicon layer.

### CLAIM OF PRIORITY

A claim of priority is made to Korean Patent Application 2005-00935 filed on Jan. 5, 2005, the entire contents of which are hereby incorporated by reference.

### BACKGROUND

Example embodiments of the present invention generally relate to chemical-mechanical polishing (CMP) process, and in particular to a slurry composition used in the CMP process to remove a structure including a polysilicon layer, and a method of manufacturing a semiconductor device using the slurry composition.

Chemical-mechanical polishing (CMP) process is a type of surface planarizing technique. In the CMP process, after a wafer is loaded on a rotation plate and the wafer contacts a pad of a polisher, a polishing process may be carried out while rotating the plate and the pad of the polisher while supplying slurry (or slurry compositions) thereto. In other words, while polishing the surface of the wafer mechanically by the slurry that flows between the surface of the wafer and the pad of the polisher, a chemical reaction may also occur between the slurry and the wafer surface to thereby remove a portion of the wafer surface.

In general, the slurry may contain various components depending on the type and characteristics of an object (i.e., surface) to be removed. For example, CMP slurry used to remove a polysilicon layer requires a high removal rate against the polysilicon layer, but a low removal rate against a dielectric layer such as an oxide layer, or a stopping layer such as a silicon nitride layer. However, when silica (SiO2)-series based slurry is used in the CMP process to remove a polysilicon layer, there may be a problem because the polysilicon layer may be removed fifty to hundred times faster than the removal of an oxide layer and a silicon nitride layer. As a result, the polysilicon layer may be excessively polished, which may cause a dishing or cupping phenomenon on the wafer surface. In particular, if the polysilicon layer is completely removed at a monitoring site due to the dishing phenomenon, it may not be possible to monitor whether subsequent layer(s) has been properly formed to a required thickness.

### SUMMARY OF THE INVENTION

In an embodiment of the present invention, a slurry composition includes carrier liquid, polish, a surfactant, and a positive-ionic high molecular compound. The positive-ionic compound may be one of an imino-compound or an amino-compound.

In another embodiment of the present invention, a method of manufacturing a semiconductor device includes forming a conductive pattern on a substrate, forming an insulation layer surrounding the conductive pattern, depositing a polysilicon layer on the insulation layer, and removing an upper portion of the polysilicon layer using a slurry composition, to expose an upper portion of the insulation layer and to form a polished surface of the polysilicon layer. Removing the upper portion of the polysilicon layer includes selectively forming a first passivation layer on the polysilicon layer, and selectively forming a second passivation layer on the first passivation layer, to control a removal rate of the polysilicon.

In another embodiment of the present invention, a method of polishing a polysilicon layer includes providing a slurry composition on the polysilicon layer, the slurry composition includes carrier liquid, polish, a surfactant; and a positive-ionic high molecular compound, wherein the positive-ionic compound is one of an imino-compound or an amino-compound. The method further includes selectively forming a first passivation layer on the polysilicon layer by the surfactant, selectively forming a second passivation layer on the first passivation layer by the positive-ionic high molecular compound, and polishing the polysilicon layer with the slurry compound.

Other example embodiments of the present invention are directed to slurries that do not excessively remove a polysilicon layer during a CMP process.

### BRIEF DESCRIPTION OF THE DRAWINGS

The accompanying drawings are included to provide a further understanding of example embodiments of the present invention, and are incorporated in and constitute a part of this specification. The drawings illustrate the example embodiments of the present invention and, together with the description, serve to explain aspects of the present invention. In the drawings:

FIG. 1 is a graphic diagram illustrating a relation between dishing rates and concentration amounts of surfactant added to slurry compositions;

FIG. 2 is a graphic diagram illustrating a relation between dishing rates and molecular weights of polyethylenimine added to slurry compositions;

FIG. 3 is a graphic diagram illustrating a relation between dishing rates and weight % of polyethyleneimine added to slurry compositions according to an example embodiment of the present invention;

FIG. 4 is a graphic diagram illustrating a relation between dishing rates and concentration amounts of a polish added to slurry compositions according to an example embodiment of the present invention; and

FIGS. 5A through 5F are sectional views illustrating processing steps of manufacturing a semiconductor device using a CMP process with slurry composition according to an example embodiment of the present invention.

### DETAILED DESCRIPTION OF EXAMPLE EMBODIMENTS

Example embodiments of the present invention will be described below in more detail with reference to the accompanying drawings. The present invention may, however, be embodied in different forms and should not be constructed as limited to example embodiments set forth herein. Rather, these example embodiments are provided as working examples.

In the drawings, the thickness of layers and regions are exaggerated for clarity. It will also be understood that when a layer is referred to as being on another layer or substrate, it can be directly on the other layer or substrate, or intervening layers may also be present. Like numerals refer to like elements throughout the specification.

Slurry Composition

A slurry composition may be composed of carrier liquid, polishing grains, and a suspension. The carrier liquid may be used with de-ionized water. The polishing grains (polish) may be selected from various oxides, such as silica (SiO₂), alumina (Al₂O₃), ceria (CeO₂), or tri-oxy-manganese (Mn₂O₃). The size and amount of the polishing grains in the slurry composition may affect polishing efficiency. Therefore, the polishing grains may be uniform in size. The polishing grains may also be quantified to be in a range of about 0.1 through 50 weight % of the total weight % of the slurry composition.

Various materials may be added to the slurry composition. For instance, viscosity regulating agents, anti-foaming agents, and chelating agents are available as additives to adjust the slurry composition as required.

The slurry composition may be prepared in an appropriate pH range by adjusting the pH with buffering agents, or by acids and bases without buffering agents. Acids for adjusting the pH may include sulfuric acid (H₂SO₄), nitric acid (HNO₄), hydrochloric acid (HCl), phosphoric acid (H₃PO₄), and the like. Bases for adjusting the pH may include calcium hydroxide (KOH), ammonium hydroxide (NH₄OH), tri-methylamine (TMA), tri-ethylamine (TEA), tetra-methyl-ammonium hydroxide (TMAH), and the like. The pH of the slurry composition may be adjusted to at least 7, preferably in a range about 7 through 12. The pH of the slurry composition may be adjusted in a range of neutrality or basic, because if the slurry composition is too acidic it may cause degradation in the polishing efficiency.

The slurry composition may contain one or more surfactants including both hydrophilic and hydrophobic functional groups. The surfactants used in example embodiments of the present invention may be non-ionic surface active agents. The surfactants according to the example embodiments of the present invention may be polymer alcoholic materials, composed of EOx-POy in the form of copolymer as a compound of ethylene oxide (EO) and propylene oxide (PO), or EOx-POy-EOz and POx-EOy-POz in the form of a tri-block copolymer. Such surfactants may first combine with a hydrophobic surface of the polysilicon layer to form a first passivation layer. The polymer surfactant may be added in concentration amounts of at least about 0.001 weight % of the total weight % of the slurry composition. In an example embodiment, the polymer surfactant may be added in a concentration amount of about 0.001 through 5 weight % thereof.

The EOx-POy block copolymer alcohol may be selected from a first alcoholic group defined by Formula 1 and a second alcoholic group defined by Formula 2.
CH₃—(CH₂)ₙ—(CH(CH₃)CH₂O)_{y}—(CH₂CH₂O)ₓ—OH [Formula 1]
R₁—C₆H₄O—(CH(CH₃)CH₂O)_{y}—(CH₂CH₂O)ₓ—OH [Formula 2]

In Formulas 1 and 2: R₁ may be C₉H₁₉ or C₈H₁₇; n is an integer wherein 3≦n≦22; x is an integer wherein 1≦x≦30; and y is an integer wherein 1≦y≦30.

The EOx-POy tri-block copolymer alcohol may be selected from a first alcoholic group defined by Formula 3 and a second alcoholic group defined by Formula 4.
(CH₂CH₂O)_{z}—(CH(CH₃)CH₂O)_{y}—(CH₂CH₂O)ₓ—OH [Formula 3]
(CH(CH₃)CH₂O)_{z}—(CH₂CH₂O)_{y}—(CH(CH₃)CH₂O)ₓ—OH [Formula 4]

In Formulas 3 and 4: x is an integer wherein 1≦x≦30; y is an integer wherein 1≦y≦30; and z is an integer wherein 1≦z≦30.

The slurry composition may further include a positive-ionic high molecular compound. The positive-ionic high molecular compound may be selected from one among imino-groups or amino-groups. The positive-ionic high molecular compound used should have the largest molecular weight as possible to reduce excessive removal of the polysilicon layer, for example, the molecular weight may be in a range of about 800 through 750000. The additive of the positive-ionic high molecular compound may be in a concentration amount of about 0.001 through 1 weight %. The positive-ionic high molecular compound may form a second passivation layer in addition and on the first passivation layer, and the targeted polysilicon layer. As a result, the positive-ionic high molecular compound may be more effective in restraining the excessive removal of the polysilicon layer as compared to using only the surfactant.

Comparative Experiment Data

Silicon nitride layer: after forming a tetra-ethyl-ortho-silicate (TEOS) layer on a bare 8-inch wafer to a thickness about 1000 Å, a silicon nitride layer was deposited on the TEOS layer to a thickness about 5000 Å.

Oxide layer: a TEOS layer was formed on a bare 8-inch wafer to a thickness about 8000 Å.

Polysilicon layer: after forming a TEOS layer on a bare 8-inch wafer to a thickness about 1000 Å, a polysilicon layer was deposited on the TEOS layer to a thickness about 5000 Å.

Pattern Wafer

After forming a TEOS layer on a bare 8-inch wafer to a thickness about 1000 Å, the wafer was patterned and etched, and the resultant structure had line widths of 8 μm, 16 μm, 64 μm, and 125 μm, respectively, resulting in grooves having a height of 5000 Å. Then, a polysilicon layer was deposited over the grooved structure to a height of 5000 Å.

CMP Condition

Experimental examples of the present invention were tested using F-REX 200 equipment by EBARA Co. and MIRRA equipment by AMAT Co. The F-REX 200 equipment was used in polishing the blanket wafer to measure the removal rate during polishing, while the MIRRA equipment was used in polishing the pattern wafer to measure a dishing rate. A Rodel IC 1000 was used for the top polishing pad and a Rodel Suba 4 was used as the sub-polishing pad for the F-REX 200 equipment. The rotation speed of the polishing plate attached to the polishing pad was set at about 80 rpm. The rotation speed of the polishing head was about 72 rpm; and the speed at which a slurry composition was supplied was about 200 ml/min. The CMP processing time for the blanket wafer was about 60 seconds. The CMP processing time for the pattern wafer was established by calculating a time to remove 10000 Å of polysilicon layer after completing the CMP process for the blanket wafer.

### EXPERIMENTAL EXAMPLE 1

This example experiment was proceeded to find the speeds for removing an oxide layer, a silicon nitride layer, and a polysilicon layer, and the dishing rate of the polysilicon layer when a slurry composition contained an non-ionic surfactant, and a dishing rate of the polysilicon layer. Colloidal silica as a polish was added to the slurry composition in a quantity of 10 weight % of the total weight % of the slurry composition; the pH was adjusted to 11. The non-ionic surfactant was used with a compound in which x=13, y=30, and z=13, among the ethylene oxide—propylene oxide—ethylene oxide tri-block polymers (EOx-POy-EOz). Table 1 summarizes the CMP process after adding the non-ionic surfactant into the slurry composition in varying concentration amounts.

TABLE 1

| | 0 | 0.005 | 0.01 | 0.05 |
|---|---|---|---|---|
| Non-ionic surfactant | weight % | weight % | weight % | weight % |
| Polysilicon | 7997 | 5983 | 5159 | 2216 |
| removal rate (Å/min) | | | | |
| Silicon oxide | 40.9 | 50.6 | 49.8 | 53.5 |
| removal rate (Å/min) | | | | |
| Silicon nitride | 15.9 | 22.3 | 23.3 | 23.6 |
| removal rate (Å/min) | | | | |
| Selectivity | 195.6 | 118.1 | 103.6 | 41.4 |
| (polysilicon/silicon | | | | |
| oxide) | | | | |
| Selectivity | 503.1 | 268.2 | 221 | 93.7 |
| (polysilicon/silicon | | | | |
| nitride) | | | | |

As illustrated in Table 1, as the concentration amounts of the surfactant increased, the removal rate of the polysilicon layer decreased. Specifically, the removal rate of the polysilicon layer when the surfactant was about 0.05 weight % decreased almost to half as compared when the surfactant was about 0.01 weight %. If the removal rate of the polysilicon layer decreases, it takes a longer amount of time to conduct the CMP process, which increases the entire processing time. Thus, the concentration amount of surfactant added may be less than about 0.01 weight %. The concentration amount of the surfactant may be in a range about 0.001 through 0.01 weight %.

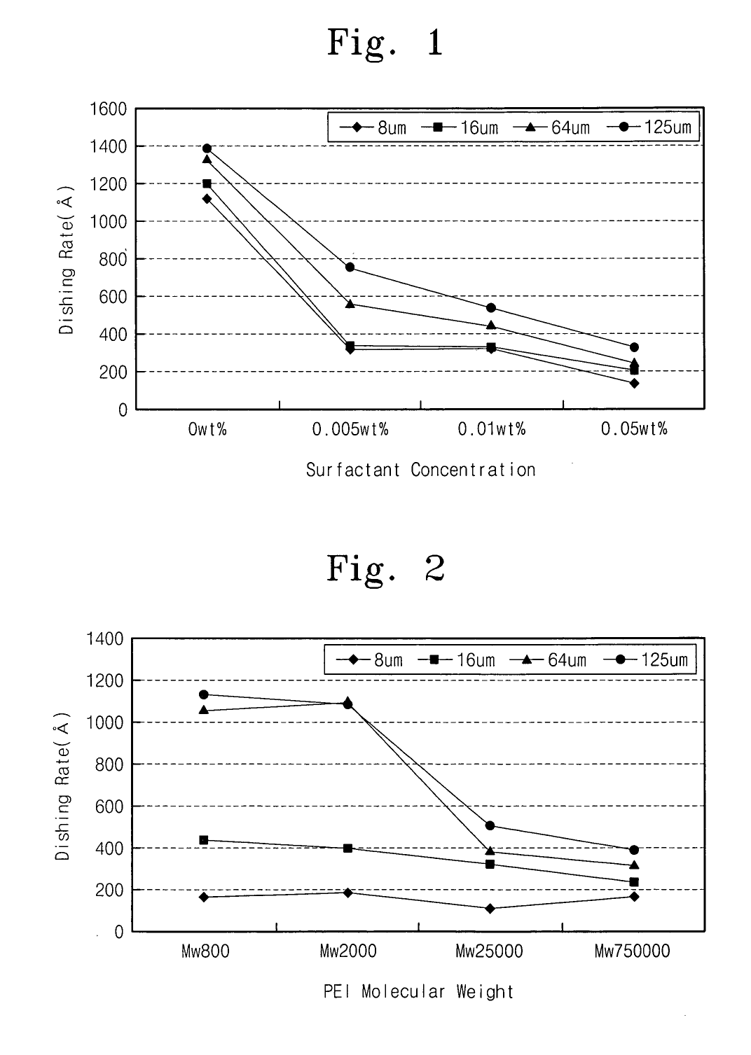

FIG. 1 illustrates a relationship between a dishing rate and a variation in the concentration amount of surfactant added, the increase of the concentration amount of surfactant added caused a significant decrease in the dishing rate.

### EXPERIMENTAL EXAMPLE 2

In this example experiment, colloidal silica was prepared in about 10 weight % of the total weight % of the slurry composition, and the same surfactant as that used in Example 1 was added in a concentration amount about 0.01 weight %. In addition, polyethylenimine (PEI) with various molecular weights were added to the slurry composition; pH was adjusted to about 11.

Table 2 summarizes the results of the CMP process when the molecular weight of the PEI was varied.

TABLE 2

| | No | Mw: | Mw: | Mw: | Mw: |
|---|---|---|---|---|---|
| PEI | PEI | 800 | 2000 | 25000 | 75000 |
| Polysilicon | 5159 | 4958 | 5201 | 5124 | 5227 |
| removal rate (Å/min) | | | | | |
| Silicon oxide | 49.8 | 52.6 | 48.5 | 45.1 | 36.4 |
| removal rate (Å/min) | | | | | |
| Silicon nitride | 23.3 | 25.4 | 22 | 19.6 | 17.4 |
| removal rate (Å/min) | | | | | |
| Selectivity | 103.6 | 94.3 | 107.2 | 113.6 | 143.6 |
| (polysilicon/silicon | | | | | |
| oxide) | | | | | |
| Selectivity | 221 | 195.2 | 236.4 | 261.4 | 300.4 |
| (polysilicon/silicon | | | | | |
| nitride) | | | | | |

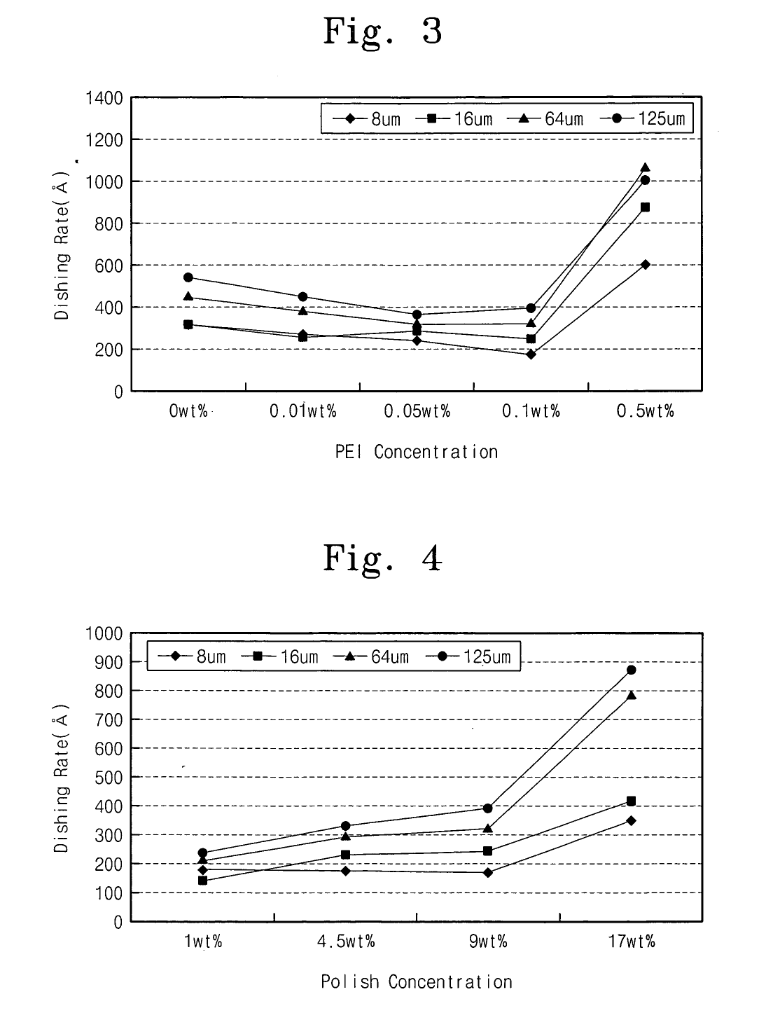

When the PEI having a molecular weight of about 800 was added to the slurry composition, the removal rate of the polysilicon layer was reduced more than if no PEI was added thereto. FIG. 2 illustrates the dishing rates in accordance with the variation in the molecular weight of the PEI, when the molecular weight of the PEI was about 800 or about 2000, the dishing rate of the polysilicon layer were greater than before adding the PEI thereto. The dishing rate did not decrease as compared to no PEI until the molecular weight of the PEI was over about 25000. Such a substantial effect of reducing the dishing rate of the polysilicon layer occurred when the polysilicon layer had a large line width of about 64 μm or about 125 μm. This effect of reducing the dishing rate improved as the molecular weight of the PEI is in a range between about 25000 through 750000.

### EXPERIMENTAL EXAMPLE 3

Colloidal silica were prepared in about 10 weight % of the total weight % of the slurry composition, and the same surfactant as that used in Example 1 was added in a concentration amount of 0.01 weight %. Further, polyethylenimine (PEI) with a molecular weight of about 750000 were added to the slurry composition in varying amounts; the pH was adjusted to about 11.

Table 3 summarizes the results of the CMP process with varying the concentration amount of the PEI.

TABLE 3

| | 0 | 0.01 | 0.05 | 0.1 | |
|---|---|---|---|---|---|
| | weight | weight | weight | weight | 0.5 |
| PEI | % | % | % | % | weight % |
| Polysilicon | 5159.2 | 4874.2 | 4906.5 | 5227.2 | 4047.1 |
| removal rate (Å/min) | | | | | |
| Silicon oxide | 49.8 | 46.6 | 40.5 | 36.4 | 15.1 |
| removal rate (Å/min) | | | | | |
| Silicon nitride | 23.3 | 23.1 | 20 | 17.4 | 4.3 |
| removal rate (Å/min) | | | | | |
| Selectivity | 103.6 | 104.6 | 121.1 | 143.8 | 267.4 |
| (polysilicon/silicon | | | | | |
| oxide) | | | | | |
| Selectivity | 221.4 | 210.7 | 299.6 | 245.3 | 950.2 |
| (polysilicon/silicon | | | | | |
| nitride) | | | | | |

While the removal rate of the polysilicon layer was reduced slightly when the PEI was added to the slurry composition as compared to when no PEI was added thereto, the removal rate increased as the concentration amount of the PEI increased. However, the removal rate of the polysilicon layer surprisingly decreased when the added concentration of the PEI was about 0.5 weight % rather than with about 0.1 weight %.

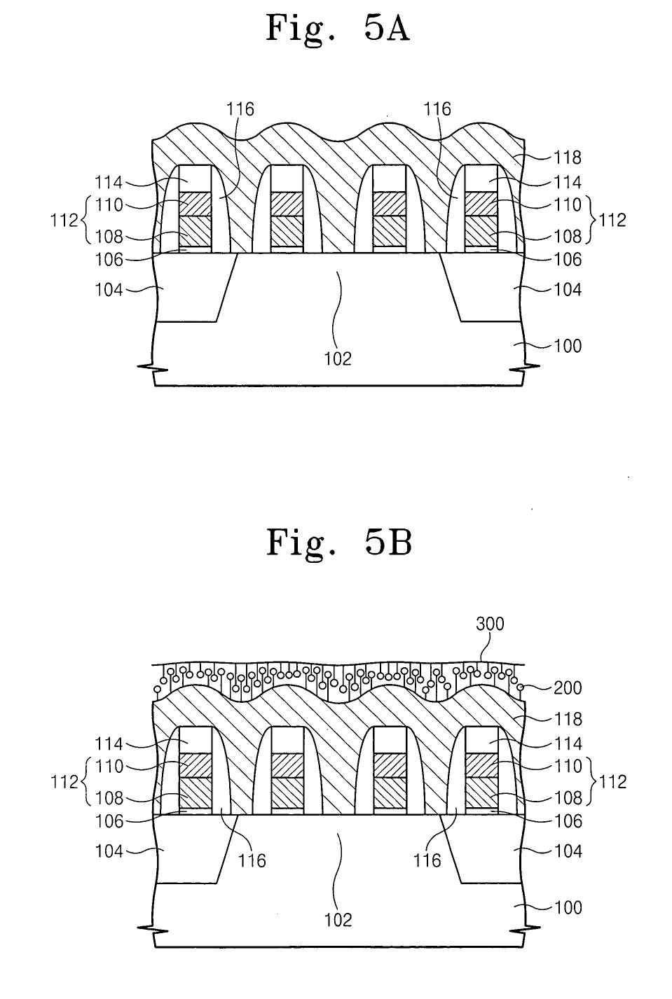

FIG. 3 illustrates dishing rates in accordance with the concentration amounts of the PEI. It can be seen that the dishing rate increased when the concentration amount of the PEI was over about 0.1 weight %. The dispersiveness of the slurry composition may deteriorate, which may increase the dishing rate, when the concentration amount of the PEI is over about 0.1 weight %.

### EXPERIMENTAL EXAMPLE 4

In this example experiment, the same surfactant as that used in Example 1 was added in a concentration amount of about 0.01 weight % of the total weight % of the slurry composition. The PEI with a molecular weight of about 750000 was added in concentration amount of 0.1 weight % to the slurry composition; the pH was adjusted to about 11.

The results of the CMP process when varying the concentration amount of the polish are shown in Table 4, where colloidal silica was used as the polish.

TABLE 4

| Colloidal silica | 1 weight % | 4.5 weight % | 9 weight % | 17 weight % |
|---|---|---|---|---|
| Polysilicon | 3726 | 5123.3 | 5227.2 | 5142.6 |
| removal rate | | | | |
| (Å/min) | | | | |
| Silicon oxide | 20.2 | 23.6 | 36.4 | 56.4 |
| removal rate | | | | |
| (Å/min) | | | | |
| Silicon nitride | 10.6 | 18.4 | 17.3 | 27.1 |
| removal rate | | | | |
| (Å/min) | | | | |
| Selectivity | 162.1 | 216.7 | 143.7 | 91.3 |
| (polysilicon/ | | | | |
| silicon oxide) | | | | |
| Selectivity | 309 | 278.5 | 302.2 | 189.8 |
| (polysilicon/ | | | | |
| silicon nitride) | | | | |

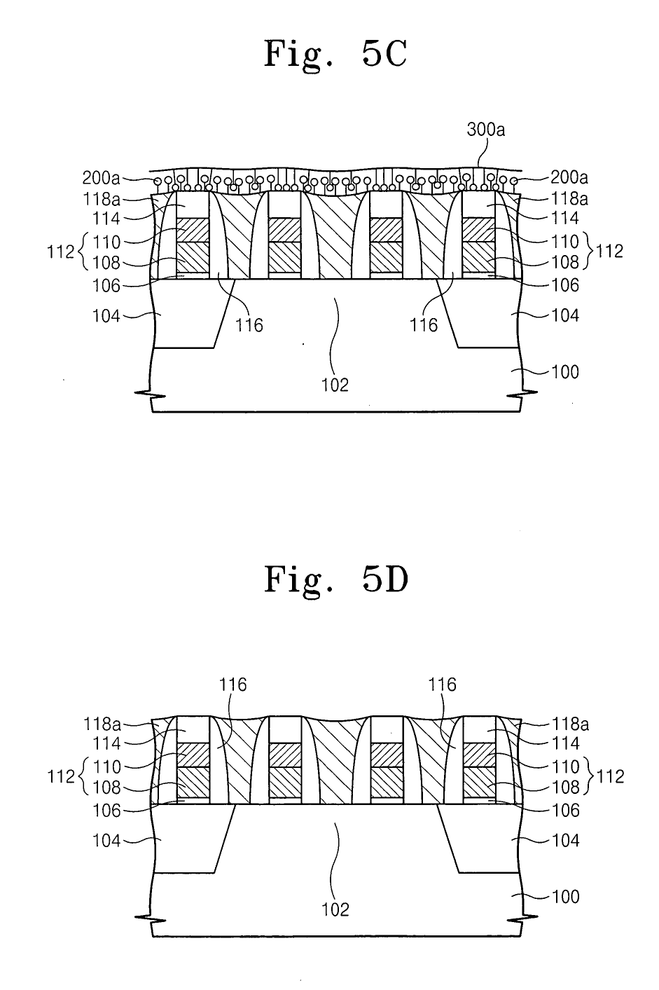

From Table 4 showing the result of this experiment, the removal rates of the polysilicon layer(5123.3 Å/min, 5227 Å/min, 5142.6 Å/min) were obtained in approximate levels but the removal rate (3726 Å/min) in the case of adding the polish(colloidal silica) in the amount of about 1 weight %. However, as illustrated in FIG. 4, as the concentration amount of the polish increased, the dishing rate also increased. Specifically, when the concentration amount of the polish was over about 9 weight %, the dishing rate increased almost 2 fold. Therefore, the concentration amount of the polish may be in a range about 0.1 to about 9 weight %.

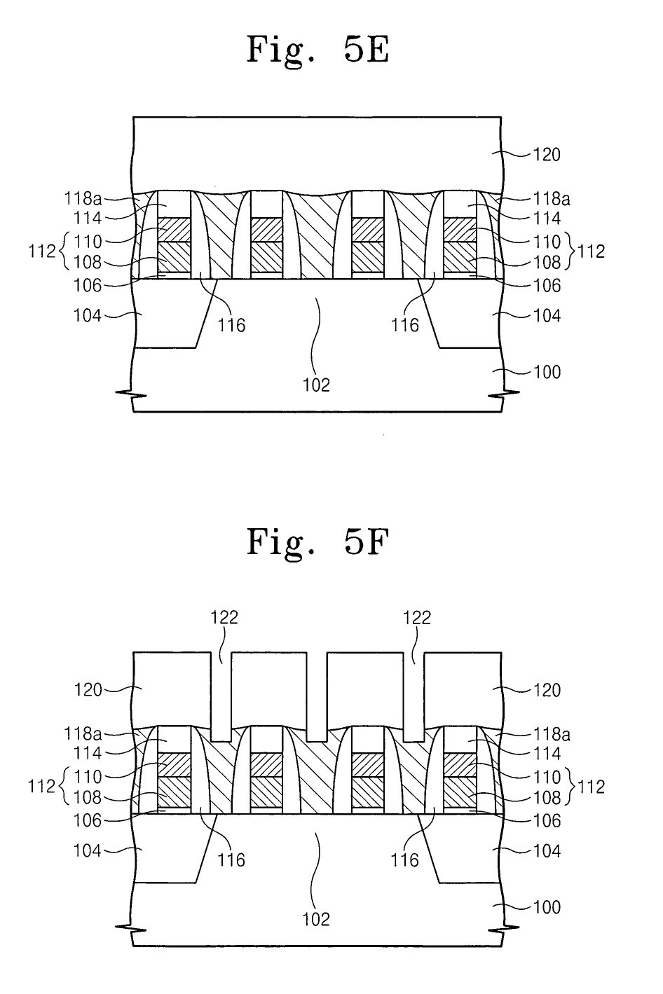

FIGS. 5A through 5F are sectional views illustrating the manufacture of a semiconductor device using a CMP process with slurry composition according to an example embodiment of the present invention.

Referring to FIG. 5A, a substrate 100 may have an active region 102 and a field isolation region 104. The active region 102 may have electrical contacts, including one or more doped regions (not shown). An insulation (or dielectric) layer 106 may be formed on the substrate 100, and a gate electrode 112 may be formed on the insulation layer 106. The gate electrode 112 may be a stacked polysilicon layer 108 and metal silicide layer 110. The metal silicide 110 may be formed from coherently reacting polysilicon with a metal for example tungsten, nickel, or a metal alloy. The gate electrode 112 may be protected by a capping layer 114 including an oxide layer and/or a silicon nitride layer, and a spacer structure 116. A polysilicon layer 118 may be deposited on the resultant structure in order to complete the electrical contacts to the substrate 100.

The polysilicon layer 118 may be removed by a CMP process to expose the capping layer 114. As illustrated in FIGS. 5B and 5C, during the CMP process and using the slurry composition according to an example embodiment of the present invention, surfactant 200 and positive-ionic high molecular compound 300 may be adhered onto the polysilicon layer 118, resulting in first and second passivation layers. The first and second passivation layers may function to restrain the removal rate of the polysilicon layer 118, thereby preventing the polysilicon layer 118 from being excessively removed. By removing top portions of the polysilicon layer 118, polysilicon plugs 118a may be formed between the spacer structures 116. The surfactant 200 and the positive-ionic high molecular compound 300a disposed on the spacer structures 116, the capping layers 114, and the polysilicon plugs 118a, and which may regulate the removal rates of the polysilicon layer, the oxide layer, and the silicon nitride layer, resulting in a planar structure as illustrated FIG. 5D. The polished surface of the polysilicon layer 118 may be positioned slightly lower than the surface level defined by the capping layer 114 or the spacer structure 116, which may act as a stopping layer against the CMP process by about 25 to 50 Å.

As illustrated in FIG. 5E, after completing the CMP process, an interlevel insulation (or dielectric) layer 120 may be further deposited on the resultant structure. The interlevel insulation layer 120 may be formed of an oxide layer. Thereafter, a photoresist contact pattern (not shown) may be formed on the interlevel insulation layer 120. The interlevel insulation layer 120 may be selectively etched away to form contact openings 122 that exposes the surfaces of the polysilicon plugs 118a through the interlevel insulation layer 120.

The surfactant 200 and positive-ionic high molecular compound 300 added to the slurry composition, according to example embodiments of the present invention, may restrain the excessive removal of the polysilicon layer 118, facilitate substantially planarizing the surfaces of the capping layers 114, the spacer structures 116, and the polysilicon plugs 118a. As a result, as illustrated in FIG. 5F, by the etching process for the contact openings 112, the top surfaces of the polysilicon plugs 118a are exposed. Thus, example embodiments of the present invention may effectively overcome the problems arising from the phenomenon that the interlevel insulation layer 120 may partially remain at bottoms of the contact openings 112 due to under-etching caused by the over-removal of the polysilicon layer.

Although the present invention has been described in connection with the example embodiments of the present invention, it will be apparent to those skilled in the art that various substitution, modifications and changes may be thereto without departing from the scope of the example embodiment of the present invention.

What is claimed is:

1. A slurry composition, comprising:
carrier liquid;
polish;
a surfactant; and
a positive-ionic high molecular compound.

2. The slurry composition as set forth in claim 1, wherein the positive-ionic high molecular compound is one of an imino-compound or an amino-compound.

3. The slurry composition as set forth in claim 1, wherein the positive-ionic high molecular compound is about 0.001 to about 1 weight % of a total weight % of the slurry composition.

4. The slurry composition as set forth in claim 1, wherein a molecular weight of the positive-ionic high molecular compound is about 800 to 750000.

5. The slurry composition as set forth in claim 1, wherein a pH of the slurry composition is in a range about 7 to 12.

6. The slurry composition as set forth in claim 5, wherein the pH is about 11.

7. The slurry composition as set forth in claim 1, wherein the surfactant is a non-ionic surfactant, and the non-ionic surfactant is at least one compound selected from the group consisting of ethylene oxide—propylene oxide block copolymer alcohol and ethylene oxide—propylene oxide—ethylene oxide tri-block polymer.

8. The slurry composition as set forth in claim 7, wherein the ethylene oxide—propylene oxide block copolymer alcohol is defined by:
CH₃—(CH₂)ₙ—(CH(CH₃)CH₂O)_{y}—(CH₂CH₂O)ₓ—OH or
R₁C₆H₄O—(CH(CH₃)CH₂O)_{y}—CH₂CH₂O)ₓ—OH,
wherein R₁ is C₉H₁₉ or C₈H₁₇; n is 3≦n≦22; x is 1≦x≦30; and y is 1≦y≦30.

9. The slurry composition as set forth in claim 7, wherein the ethylene oxide—propylene oxide tri-block polymer is defined by:
(CH₂CH₂O)_{z}—(CH(CH₃)CH₂O)_{y}—(CH₂CH₂O)ₓ—OH or
CH(CH₃)CH₂O)_{z}—(CH₂CH₂O)_{y}—(CH(CH₃)CH₂0)ₓ—OH,
wherein x is 1≦x≦30; y is 1≦y≦30; and z is 1≦z≦30.

10. The slurry composition as set forth in claim 1, wherein the polishing grains are selected from the group consisting of silica, alumina (Al₂O₃), ceria, and tri-oxy-manganese.

11. The slurry composition as set forth in claim 10, wherein the selected polishing grains concentration amount is about 0.1 weight % to about 50 weight % of the total molecular weight % of the slurry composition.

12. A method of manufacturing a semiconductor device, comprising:
forming a conductive pattern on a substrate;
forming an insulation layer surrounding the conductive pattern;
depositing a polysilicon layer on the insulation layer; and
removing an upper portion of the polysilicon layer using a slurry composition, to expose an upper portion of the insulation layer and to form a polished surface of the polysilicon layer,
wherein removing the upper portion of the polysilicon layer includes selectively forming a first passivation layer on the polysilicon layer, and selectively forming a second passivation layer on the first passivation layer, to control a removal rate of the polysilicon layer.

13. The method as set forth in claim 12, wherein the slurry includes a non-ionic surfactant, and the non-ionic surfactant forms the first passivation layer, and wherein the non-iconic surfactant is at least one compound selected from the group consisting of ethylene oxide—propylene oxide block copolymer alcohol and ethylene oxide—propylene oxide—ethylene oxide tri-block polymer.

14. The method as set forth in claim 12, wherein the slurry includes a positive-ionic high molecular compound, the positive-ionic high molecular compound forms the second passivation layer, and wherein the positive-ionic compound is one of an imino-compound or an amino-compound.

15. The method as set forth in claim 13, wherein the ethylene oxide—propylene oxide block copolymer alcohol is defined by:
CH₃—(CH₂)ₙ—(CH(CH₃)CH₂O)_{y}—(CH₂CH₂O)ₓ—OH or
R₁—C₆H₄O—(CH(CH₃)CH₂O)_{y}—CH₂CH₂O)ₓ—OH,
wherein R₁ is C₉H₁₉ or C₈H₁₇; n is 3≦n≦22; x is 1≦x≦30; and y is 1≦y≦30.

16. The method as set forth in claim 13, wherein the ethylene oxide—propylene oxide tri-block polymer is defined by:
(CH₂CH₂O)_{z}—(CH(CH₃)CH₂O)_{y}—(CH₂CH₂O)ₓ—OH or
CH(CH₃)CH₂O)_{z}—(CH₂CH₂O)_{y}—(CH(CH₃)CH₂O)ₓ—OH,
wherein x is 1≦x≦30; y is 1≦y≦30; and z is 1≦z≦30.

17. The method as set forth in claim 14, wherein the positive-ionic high molecular compound is about 0.001 to about 1 weight % of a total weight % of the slurry composition.

18. The method as set forth in claim 14, wherein a molecular weight of the positive-ionic high molecular compound is about 800 to 750000.

19. A method of polishing a polysilicon layer, comprising:
providing a slurry composition on the polysilicon layer, the slurry composition including carrier liquid, polish, a surfactant, and a positive-ionic high molecular compound, wherein the positive-ionic compound is one of an imino-compound or an amino-compound;
selectively forming a first passivation layer on the polysilicon layer by the surfactant; and
selectively forming a second passivation layer on the first passivation layer by the positive-ionic high molecular compound to control a removal rate of the polysilicon layer.

20. The method as set forth in claim 19, wherein the positive-ionic high molecular compound is about 0.001 to about 1 weight % of a total weight % of the slurry composition.

21. The method as set forth in claim 19, wherein a molecular weight of the positive-ionic high molecular compound is about 800 to 750000.

22. The method as set forth in claim 19, wherein the surfactant is a non-ionic surfactant, and the non-ionic surfactant is at least one compound selected from the group consisting of ethylene oxide—propylene oxide block copolymer alcohol and ethylene oxide—propylene oxide—ethylene oxide tri-block polymer.

23. The method as set forth in claim 22, wherein the ethylene oxide—propylene oxide block copolymer alcohol is defined by:
CH₃—(CH₂)ₙ—(CH(CH₃)CH₂O)_{y}—(CH₂CH₂O)ₓ—OH or
R₁—C₆H₄O—(CH(CH₃)CH₂O)_{y}—CH₂CH₂O)ₓ—OH,
wherein R₁ is C₉H₁₉ or C₈H₁₇; n is 3≦n≦22; x is 1≦x≦30; and y is 1≦y≦30.

24. The method as set forth in claim 22, wherein the ethylene oxide—propylene oxide tri-block polymer is defined by:
(CH₂CH₂O)_{z}—(CH(CH₃)CH₂O)_{y}—(CH₂CH₂O)ₓ—OH or
CH(CH₃)CH₂O)_{z}—(CH₂CH₂O)_{y}—(CH(CH₃)CH₂O)ₓ—OH,
wherein x is 1≦x≦30; y is 1≦y≦30; and z is 1≦z≦30.
